(19) United States
(12) Patent Application Publication
(10) Pub. No.: US 2026/0152848 A1
(43) Pub. Date: Jun. 4, 2026

(54) LINEAR FEEDTHROUGH AND PROCESSING APPARATUS FOR SEMICONDUCTOR SUBSTRATE USING THE SAME

(71) Applicant: SEALINK CORP., Seoul (KR)

(72) Inventor: Hee Jang RHEE, Gunpo-si Gyeonggi-do (KR)

(73) Assignee: SEALINK CORP., Seoul (KR)

(21) Appl. No.: 19/091,032

(22) Filed: Mar. 26, 2025

(30) Foreign Application Priority Data
Nov. 29, 2024 (KR) 10-2024-0174280
Dec. 26, 2024 (KR) 10-2024-0197416

(51) Int. Cl. C23C 16/44; C23C 16/458

(52) U.S. Cl. CPC C23C 16/4409; C23C 16/4408; C23C 16/4583

(57) ABSTRACT

A linear feedthrough is provided. The linear feedthrough according to an embodiment of the disclosure includes a hollow housing connected to the chamber, a shaft accommodated in the housing, and having one end penetrating a wall of the chamber and connected to a susceptor to lift/lower the susceptor, a sealing portion disposed in the housing to seal a gap between the housing and the shaft, and including a plurality of seals to perform sealing even when the shaft performs a linear motion within the housing, and purge flow paths disposed between the plurality of seals and discharging foreign substances between the plurality of seals to the outside.

### CROSS-REFERENCE TO RELATED APPLICATIONS

This application claims priority to Korean Patent Application No. 10-2024-0174280 filed on Nov. 29, 2024, and Korean Patent Application No. 10-2024-0197416 filed on Dec. 26, 2024, the entire contents of which are herein incorporated by reference.

### BACKGROUND

### 1. Field

The disclosure relates to a linear feedthrough and a semiconductor substrate processing apparatus using the same, and more particularly to, a linear feedthrough that prevents fluid from leaking between a shaft and a housing, and a semiconductor substrate processing apparatus using the same.

### 2. Description of the Related Art

Processing apparatuses for semiconductor substrates are used for mass production of integrated circuits. Physical vapor deposition (PVD) such as sputtering and chemical vapor deposition (CVD) using chemical reactions are used to deposit a thin film of a certain thickness on a substrate such as a semiconductor wafer or glass. Examples of PVD include atmospheric pressure CVD (APCVD), low pressure CVD (LPCVD), plasma organic CVD (PECVD), etc. In addition, furnace equipment for heat treatment of substrates is used for film treatment, oxidation, annealing, and diffusion treatment of impurities of semiconductor wafers.

Here, PECVD is a method of depositing a thin film by applying an electric field to mixed gas in a chamber (reactor) and forming plasma, and the thin film is deposited using radical particles among cations, anions, electrons, radicals, etc. generated during plasma formation. Radical particles are very unstable and have the property of easily chemically bonding with other elements even at low temperatures, and are used as means of deposition in PECVD.

In such a deposition apparatus using plasma, a susceptor allows a semiconductor substrate to be settled and a lifting/lowering motion for stable deposition. In the related art, a bellows was used on a lifting rod to lift and lower the susceptor while maintaining airtightness.

The bellows is to maintain airtightness during a linear motion of lifting/lowering and is a corrugated pipe formed by welding a plurality of metal plates. However, because the bellows is manufactured by welding, cracks occur when used for a long time, making it impossible to maintain airtightness. When cracks occur in the bellows, there is a problem that contamination may occur in the chamber due to the generation of particles.

### SUMMARY

The disclosure is directed to providing a linear feedthrough which is a linear motion sealing device that does not require a bellows and a lifting/lowering rod, thereby making the structure very compact and simple, and integrating a sealing function and a lifting/lowering function, and a semiconductor substrate processing apparatus using the same.

The disclosure also provides a linear and rotational motion sealing device that does not require a separate supply of lubricant, and a semiconductor substrate processing apparatus using the same.

The disclosure is also directed to providing a linear feedthrough capable of preventing foreign substances such as particles from a chamber from flowing into the linear motion sealing device, and preventing foreign substances from the linear feedthrough from flowing to the chamber, and a semiconductor substrate processing apparatus using the same.

The solutions of the disclosure are not limited to the above-mentioned contents, and other technical problems not mentioned will be clearly understood by one of ordinary skill in the art from the following description.

According to an embodiment of the disclosure, a linear feedthrough mounted on a chamber processing a semiconductor substrate while lifting/lowering a susceptor loading the semiconductor substrate includes a hollow housing connected to the chamber, a shaft accommodated in the housing, and having one end penetrating a wall of the chamber and connected to the susceptor to lift/lower the susceptor, a sealing portion disposed in the housing to seal a gap between the housing and the shaft, and including a plurality of seals to perform sealing even when the shaft performs a linear motion within the housing, and purge flow paths disposed between the plurality of seals and discharging foreign substances between the plurality of seals to the outside.

The linear feedthrough further includes a bushing supporting the linear motion of the shaft in the chamber between the housing and the shaft, and the plurality of seals may include three lip seals each having a curved lip formed on an inner circumferential surface of an annular sealing, and the bushing, a first lip seal, a first purge flow path, a second lip seal, a second purge flow path, and a third lip seal may be sequentially arranged from the chamber within the housing.

The housing may include a first inner diameter portion and a second inner diameter portion having different inner diameters, the bushing may be disposed in the first inner diameter portion, the plurality of lip seals and the purge flow paths may be disposed in the second inner diameter portion, and an inner diameter of the first inner diameter portion may be greater than an inner diameter of the second inner diameter portion.

One or more O-rings may be provided on an outer circumferential surface of the bushing in contact with an inner diameter portion of the housing to prevent relative rotation between the bushing and the housing.

A pressure sensor capable of measuring pressure may be provided in each of the first purge flow path and the second purge flow path.

Each of the lip seals may have a shape in which a plurality of curved lip portions are provided on one body portion.

At least two of the plurality of curved lip portions may be curved in different directions.

An annular anti-rotation member may be provided on an outer circumferential surface of each of the lip seals facing the housing to prevent relative rotation of each of the lip seals with the housing within the housing.

According to an embodiment of the disclosure, a semiconductor substrate processing apparatus processing a semiconductor substrate includes a chamber accommodating the semiconductor substrate, a susceptor provided in the chamber to load the semiconductor substrate, and a linear feedthrough mounted on the chamber and sealing the chamber while lifting/lowering the susceptor, wherein the linear feedthrough includes a hollow housing connected to the chamber, a shaft accommodated in the housing, and having one end penetrating a wall of the chamber and connected to the susceptor to lift/lower the susceptor, a sealing portion disposed in the housing to seal a gap between the housing and the shaft, and including a plurality of seals to perform sealing even when the shaft performs a linear motion within the housing, and purge flow paths disposed between the plurality of seals and discharging foreign substances between the plurality of seals to the outside.

### BRIEF DESCRIPTION OF THE DRAWINGS

The above and other features and advantages of the present invention will become more apparent by describing in detail exemplary embodiments thereof with reference to the attached drawings in which:

FIG. 1 is a diagram illustrating a linear feedthrough and a semiconductor substrate processing apparatus using the same, according to an embodiment of the disclosure;

FIGS. 2A and 2B are diagrams illustrating a shaft being lifted and lowered respectively in the linear feedthrough according to an embodiment of the disclosure;

FIG. 3 is a diagram illustrating a detailed structure of the linear feedthrough according to an embodiment of the disclosure; and

FIGS. 4A, 4B, and 4C illustrate various lip seals that may be used in the linear feedthrough according to an embodiment of the disclosure.

### DETAILED DESCRIPTION

Embodiments will be described more fully hereinafter with reference to the accompanying drawings so that they may be easily implemented by one of ordinary skill in the art to which the disclosure belongs. However, the disclosure may be implemented in different forms and should not be construed as being limited to the embodiments set forth herein. In addition, in order to clearly explain an embodiment of the disclosure in the drawings, parts that are not related to the explanation are omitted.

The terms used herein are only used to describe particular embodiments, and are not intended to limit the disclosure. Singular expressions used herein are intended to include plural expressions as well unless the context clearly indicates otherwise.

The terms such as “comprise,” “include,” or “have” used herein may be understood as being intended to specify the presence of stated features, numbers, steps, operations, elements, components, or combinations thereof, but do not preclude the presence or addition of one or more other features, numbers, steps, operations, elements, components, or combinations thereof.

In addition, the following embodiments are provided to more clearly explain to one of average knowledge in the art, and the shape and size of elements in the drawing may be exaggerated for clearer explanation.

Hereinafter, preferred embodiments according to the disclosure will be described with reference to the accompanying drawings.

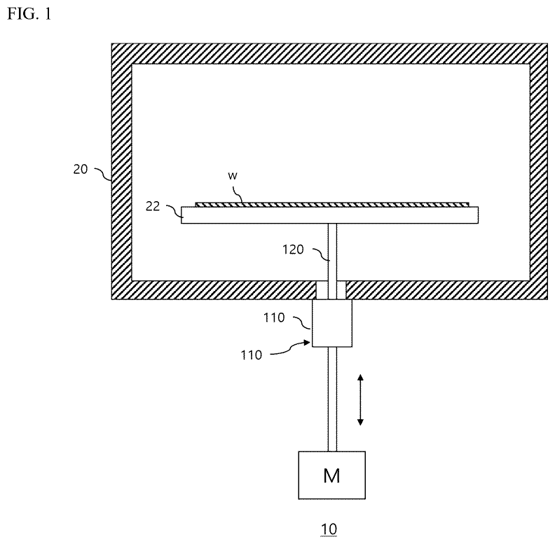

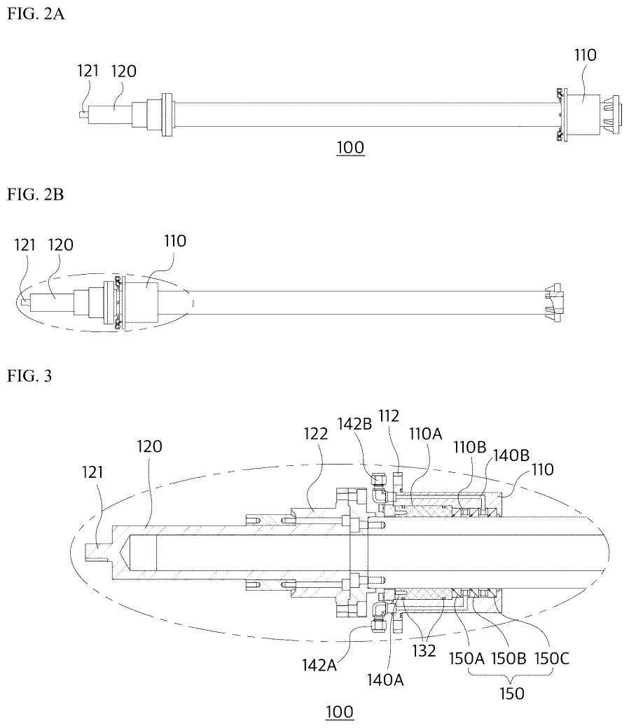

FIG. 1 is a diagram illustrating a linear feedthrough and a semiconductor substrate processing apparatus using the same, according to an embodiment of the disclosure. FIGS. 2A and 2B are diagrams illustrating a shaft being lifted and lowered respectively in the linear feedthrough according to an embodiment of the disclosure. FIG. 3 is a diagram illustrating a detailed structure of the linear feedthrough according to an embodiment of the disclosure.

Referring to FIGS. 1 to 3, a semiconductor substrate processing apparatus 10 according to an embodiment of the disclosure may include a linear feedthrough 100 and a chamber 20. Chemical vapor deposition (CVD) equipment, furnace equipment, etching equipment, etc. may be examples of the semiconductor substrate processing apparatus 10. The semiconductor substrate processing apparatus 10 may include a loading unit 22 capable of loading semiconductor wafers inside the chamber 20 and the linear feedthrough 100 lifting/lowering the loading unit 22. The linear feedthrough 100 may lift/lower the loading unit 22 at an appropriate speed and simultaneously prevent process gas in the chamber 20 from flowing to outside the chamber 20 or foreign substances outside the chamber 20 from flowing into the chamber 20.

The linear feedthrough 100 according to an embodiment of the disclosure may be mounted on the chamber 20 while lifting/lowering a susceptor (the loading unit 22) loading a semiconductor substrate. The linear feedthrough 100 may include a hollow housing 110, a shaft 120, a sealing portion 150, and purge flow paths 140A and 140B.

The hollow housing 110 may have a flange portion 112 provided at one end so that the flange portion 112 may be connected to the chamber 20, and may accommodate the shaft 120 inside so that the shaft 120 may enable a linear motion.

The shaft 120 may be mounted inside the hollow housing 110 to enable a linear motion, and have one end 121 penetrating a wall of the chamber 20 and connected to the susceptor 22 to lift/lower the susceptor 22.

The sealing portion 150 may be disposed in the housing 110 to seal a gap between the housing 110 and the shaft 120, and include a plurality of seals 150: 150A, 150B, and 150C to perform sealing even when the shaft 120 performs a linear motion within the housing 110. In the present embodiment, each of the plurality of seals 150 may be a lip seal. That is, each of the plurality of seals 150 may have a shape in which a curved lip is formed on an inner circumferential surface of an annular sealing. The sealing portion 150 may prevent foreign substances (particles, etc.) that may occur in the linear feedthrough 100 from flowing into the vacuum chamber 20 provided in an upper side of the linear feedthrough 100, and seal the inside of the chamber 20 to maintain a vacuum. The sealing portion 150 may include the plurality of seals 150A, 150B, and 150C which are combined and disposed in the housing 110, and perform sealing even when the shaft 120 has a linear motion within the housing 110.

The purge flow paths 140A and 140B are disposed between the plurality of seals 150 to discharge foreign substances between the seals 150 to the outside. In the present embodiment, three lip seals 150 are disposed, and the two purge flow paths 140A and 140B may be disposed between the seals 150, respectively. In addition, purge ports 142A and 142B to which a pneumatic apparatus for forming positive pressure or negative pressure may be connected may be respectively provided at ends of the purge flow paths 140A and 140B. That is, the first purge flow path 140A may be disposed between the first lip seal 150A and the second lip seal 150B, and the second purge flow path 140B may be disposed between the second lip seal 150B and the third lip seal 150C. The purge ports 142A and 142B A may respectively apply negative pressure to the purge flow paths 140A and 140B to suck and remove foreign substances between the first, second, and third lip seals 150A, 150B and 150C. In addition, the purge flow paths 140A and 140B may serve to prevent the process gas in the chamber 20 from being discharged to the outside through the linear feedthrough 100.

The linear feedthrough 100 according to an embodiment of the disclosure may further include a bushing 130. The bushing 130 is provided to reduce frictional force during the linear motion of the shaft 120 within the housing 110 by penetrating the shaft 120 and being coupled to the inner circumferential surface of the housing 110. In the present embodiment, the bushing 130 may be provided close to the chamber 20 between the housing 110 and the shaft 120. More specifically, the bushing 130, the first lip seal 150A, the first purge flow path 140A, the first lip seal 150B, the second purge flow path 140B, and the third lip seal 150C may be sequentially arranged from the chamber 20 in the housing 110.

Meanwhile, the housing 110 may be divided into two parts having different inner diameters. That is, the housing 110 may include a first inner diameter portion 110A and a second inner diameter portion 110B having different inner diameters. The bushing 130 may be disposed in the first inner diameter portion 110A, and inlet ends of the plurality of lip seals 150 and the purge flow paths 140A and 140B may be provided in the second inner diameter portion 110B. Because the inner diameter of the first inner diameter portion 110A is larger than the inner diameter of the second inner diameter portion 110B, the movement of the bushing 130 may be prevented by a step difference therebetween, and the inlet ends of the plurality of lip seals 150 and the purge flow paths 140A and 140B may be maintained without stably moving within the housing 110 by one end of the bushing 130.

Meanwhile, in an embodiment, one or more O-rings may be provided on the outer circumferential surface of the bushing 130 in contact with the first inner diameter portion 110A of the housing 110 to prevent relative rotation between the bushing 130 and the housing 110.

In an embodiment, a pressure sensor capable of measuring pressure may be provided in each of the first purge flow path 140A and the second purge flow path 140B. In an embodiment, a pressure sensor may be provided in the first purge port 142A of the first purge flow path 140A and the second purge port 142B of the second purge flow path 140B. Through the pressure sensor, a change in the pressure of the purge flow paths 140A and 140B may be measured, and accordingly, damage and abrasion of the plurality of lip seals 150 may be detected. For example, when a change in the pressure of the first purge flow path 140A is detected, damage to the first lip seal 150A or the second lip seal 150B may be inferred, and when a change in the pressure of the second purge flow path 140B is detected, damage to the second lip seal 150B or the third lip seal 150C may be inferred.

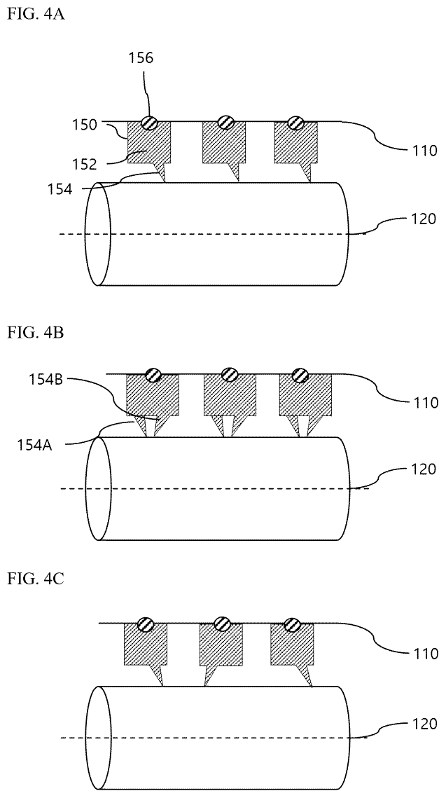

FIGS. 4A, 4B, and 4C illustrate various lip seals that may be used in the linear feedthrough according to an embodiment of the disclosure.

Referring to FIGS. 4A, 4B, and 4C, each of the lip seals 150 used in the linear feedthrough 100 according to an embodiment of the disclosure may have a shape in which a plurality of curved lip portions 154 are provided on one body portion 152.

As shown in FIG. 4A, when the three lip seals 150 are used, the lip portions 154 are curved in the same direction, as shown in FIG. 4B, lip portions 154A and 154B among the plurality of lip seals 150 may be curved in different directions, and as shown in FIG. 4C, each of the lip seals 150 includes the plurality of lip portions 154, and at least two of the plurality of curved lip portions 154 may be curved in different directions. In the case of FIG. 4A, when a vacuum is formed in the upper direction, all the lip portions 154 have shapes curved to the right to prevent foreign substances from the linear feedthrough 100 of each of the lip seals 150 from flowing to the chamber 20, and in the case of FIG. 4B, even though a vacuum is formed in either the upper direction or the lower direction, the lip portion 154A or the lip portion 154B may respond or even though one lip portion 154A is consumed or damaged, the other lip portion 154B may respond.

In an embodiment, an annular anti-rotation member 156 may be provided on an outer circumferential surface of each of the lip seals 150 toward the housing 110 to prevent relative rotation of each of the lip seals 150 with the housing 110 within the housing 110. The anti-rotation member 156 serves to further pressurize the lip seal 150 toward the shaft 120. In addition, the friction between the anti-rotation member 156 and the lip seal 150 is great compared to when there is no anti-rotation member 156, that is, when the lip seal 150 directly contacts an inner circumferential surface of the housing 110. Accordingly, the anti-rotation member 156 may suppress the lip seal 150 from rotating relative to the housing 110 within the housing 110.

In addition, when the linear feedthrough 100 is disassembled and assembled for reasons such as damage and inspection, even though the surface roughness of the housing 110 is relatively rough, the anti-rotation member 156 rubs against the inner circumferential surface of the housing 110 during a disassembly and assembly process, and thus the sealing portion 150 may minimize damage caused by low surface roughness of the housing 110. In addition, even though the anti-rotation member 156 is damaged to some extent, there is an advantage that the anti-rotation member 156 is reusable, and thus the linear feedthrough 100 may be more easily disassembled and assembled.

According to the above-described embodiments, the linear feedthrough and the semiconductor substrate processing apparatus using the same do not require a bellows and a lifting/lowering rod, thereby making the structure very compact and simple, and integrating a sealing function and a lifting/lowering function.

In addition, the linear feedthrough and the semiconductor substrate processing apparatus using the same do not require a separate supply of lubricant, prevent foreign substances such as particles from a chamber from flowing into a linear motion sealing device, and prevent foreign substances from the linear feedthrough from flowing to the chamber.

In the above-described embodiments, although an example in which the linear feedthrough is applied to the semiconductor substrate processing apparatus is described, the linear feedthrough may also be applied to various chemical processing chambers that need to perform a sealing function while requiring a lifting/lowering motion of a shaft, in addition to the semiconductor substrate processing apparatus.

In the above, the disclosure has been described with specific details such as specific components, the limited embodiments and the drawings, but these are only provided to facilitate a more general understanding of the disclosure, the disclosure is not limited to the above embodiments, and those skilled in the art may achieve various modifications and changes based on the description.

Therefore, the spirit of the disclosure should not be limited to the above-described embodiments, and the claims described below as well as all modifications equally to or equivalent to the claims shall fall within the scope of the spirit of the disclosure.

What is claimed is:

1. A linear feedthrough mounted on a chamber processing a semiconductor substrate while lifting/lowering a susceptor loading the semiconductor substrate, the linear feedthrough comprising:
a hollow housing connected to the chamber;
a shaft accommodated in the housing, and having one end penetrating a wall of the chamber and connected to the susceptor to lift/lower the susceptor;
a sealing portion disposed in the housing to seal a gap between the housing and the shaft, and comprising a plurality of seals to perform sealing even when the shaft performs a linear motion within the housing; and
purge flow paths disposed between the plurality of seals and discharging foreign substances between the plurality of seals to an outside.

2. The linear feedthrough of claim 1, further comprising a bushing supporting the linear motion of the shaft in the chamber between the housing and the shaft,
wherein the plurality of seals include three lip seals each having a curved lip formed on an inner circumferential surface of an annular sealing, and
the bushing, a first lip seal, a first purge flow path, a second lip seal, a second purge flow path, and a third lip seal are sequentially arranged from the chamber within the housing.

3. The linear feedthrough of claim 2, wherein the housing includes a first inner diameter portion and a second inner diameter portion having different inner diameters,
the bushing is disposed in the first inner diameter portion, the plurality of seals and the purge flow paths are disposed in the second inner diameter portion, and
an inner diameter of the first inner diameter portion is greater than an inner diameter of the second inner diameter portion.

4. The linear feedthrough of claim 2, wherein one or more O-rings are provided on an outer circumferential surface of the bushing in contact with an inner diameter portion of the housing to prevent relative rotation between the bushing and the housing.

5. The linear feedthrough of claim 2, wherein pressure sensor capable of measuring pressure is provided in each of the first purge flow path and the second purge flow path.

6. The linear feedthrough of claim 2, wherein each of the lip seals has a shape in which a plurality of curved lip portions are provided on one body portion.

7. The linear feedthrough of claim 6, wherein at least two of the plurality of curved lip portions are curved in different directions.

8. The linear feedthrough of claim 2, wherein an annular anti-rotation member is provided on an outer circumferential surface of each of the lip seals facing the housing to prevent relative rotation of each of the lip seals with the housing within the housing.

9. A semiconductor substrate processing apparatus processing a semiconductor substrate, the semiconductor substrate processing apparatus comprising:
a chamber accommodating the semiconductor substrate;
a susceptor provided in the chamber to load the semiconductor substrate; and
a linear feedthrough mounted on the chamber and sealing the chamber while lifting/lowering the susceptor,
wherein the linear feedthrough comprises:
a hollow housing connected to the chamber;
a shaft accommodated in the housing, and having one end penetrating a wall of the chamber and connected to the susceptor to lift/lower the susceptor;
a sealing portion disposed in the housing to seal a gap between the housing and the shaft, and comprising a plurality of seals to perform sealing even when the shaft performs a linear motion within the housing; and
purge flow paths disposed between the plurality of seals and discharging foreign substances between the plurality of seals to the outside.
